(19) United States
(12) Patent Application Publication
(10) Pub. No.: US 2011/0114970 A1
(43) Pub. Date: May 19, 2011

(54) LIGHT EMITTING DIODE STRUCTURE, A LAMP DEVICE AND A METHOD OF FORMING A LIGHT EMITTING DIODE STRUCTURE

(75) Inventors: Jinghua Teng, Singapore (SG); Soo Seng Norman Ang, Singapore (SG); Soo Jin Chua, Singapore (SG)

(73) Assignee: AGENCY FOR SCIENCE, TECHNOLOGY AND RESEARCH, Singapore (SG)

(21) Appl. No.: 12/934,710

(22) PCT Filed: Apr. 23, 2008
(86) PCT No.: PCT/SG08/00134

§ 371 Date: Jan. 25, 2011

(51) Int. Cl. H01L 33/08; H01L 33/60; H01L 33/44

(52) U.S. Cl. 257/88; 257/98; 438/29; 257/E33.072; 257/E33.075; 257/E33.06

(57) ABSTRACT

A light emitting diode structure, a lamp device and a method of forming a light emitting diode structure are provided. The structure has a substrate coated with a first reflective material; an electrode coated with a second reflective material, one or more layers of light emitting material, the layers disposed between the substrate and electrode; wherein in use, the first reflective material and second reflective material reflects light out of the structure via at least one light emitting surface and in a direction away from the electrode.

### FIELD OF INVENTION

The present invention relates broadly to a light emitting diode structure, to a lamp device and to a method of forming a light emitting diode structure.

### BACKGROUND

Light emitting diodes (LEDs) are widely used in back lighting, display and solid state lighting. It is desired in LED development to improve efficacy of LEDs. This includes factors such as improvement in materials quality, light extraction efficiency, current spreading and thermal management. These factors are becoming important for high power, high brightness applications where the chip sizes are becoming bigger and the injection currents are becoming higher.

Currently, a typical LED such as a GaN LED has light emission from either a top surface or from a substrate side using flip-chip bonding. There are a number of problems associated with these architectures.

For a typical top emitting LED, a thin Ni/Au layer, e.g. about 5 nm/5 nm, is used as a current spreading layer since p-GaN material has poor conductivity. One problem is that the Ni/Au layer is typically only semi-transparent, ie. the layer has a light transmittivity of only about 75%. This means that about 25% light is not transmitted. Furthermore, for large chips, e.g. 1 mm×1 mm or 5 mm×5 mm, the thin Ni/Au metal layer is typically not able to provide adequate current spreading, especially at high injection currents, e.g. about 1 A or 2 A. In such cases, the Ni/Au layer can disadvantageously work as a resistive heater at high currents. Further, heat generated inside the GaN material is typically only dissipated through a heat sink attached to the sapphire substrate of the LED. Thus, the heat sink is typically too far away from the heat source, considering relative dimensions of the active region to the substrate. Thus, for high power operations, thermal management is a problem which is difficult to solve using the typical top emitting LED structure.

Further, to have more light extracted out of a typical LED, the emission surface of the LED is roughened by various means. One problem is that this typically affects conductivity of the top metal layer e.g. for a top emitting LED. Roughening also requires extra process steps. Another problem is that the Snell reflection of the GaN/epoxy or air interface of e.g. the GaN LED can not be avoided due to emission via the existing metal layer.

The so-called flip-chip method has been proposed to solve the above thermal management problem using a bottom emission LED. However, the flip-chip method is a relatively complex process and is known to have its own problems. These include difficulties in flip-chip bonding and processing sapphire substrates to enhance light extraction. Further, sapphire lift off processes for a bottom emission LED is also problematic, given the typical low yield.

In addition, it is desired that different applications of the LED can have different LED architecture to make the design of the final device, comprising the LED structure, to be more flexible. For example, one major application of the LED is liquid crystal display (LCD) backlighting. A thin light spreading film is typically used to spread the light from point-source LEDs to a LCD screen. Thus, in this case, a thinner and more light-divergent LED is desired rather than e.g. the typical top emitting structure.

Hence, in view of the above, there exists a need for a light emitting diode structure, a lamp device and a method of forming a light emitting diode structure that seek to address at least one of the above problems.

### SUMMARY

In accordance with a first aspect of the present invention, there is provided a light emitting diode structure, the structure comprising a substrate coated with a first reflective material; an electrode coated with a second reflective material, one or more layers of light emitting material, the layers disposed between the substrate and electrode; wherein in use, the first reflective material and second reflective material reflects light out of the structure via at least one light emitting surface and in a direction away from the electrode.

Said at least one light emitting surface may comprise a zigzag/saw teeth type edge.

Said at least one light emitting surface may comprise a layer of passivation material for reducing light reflection.

For light emission via one light emitting surface, at least one other light emitting surface may comprise a layer of reflective material for enhancing light emission via said one light emitting surface.

For light emission via one light emitting surface, other light emitting surfaces may comprise a layer of reflective material for enhancing light emission via said one light emitting surface.

The electrode may comprise an electrode material of about 500 nm thick.

The structure may be in the form of a rectangular block comprising two long edges.

The substrate, the electrode or both may be connected to a heat sink.

The first reflective material and the second reflective material may each comprise Ag, Al or both.

The first reflective material and the second reflective material may each be more than about 10 nm thick.

In accordance with a second aspect of the present invention, there is provided a lamp device comprising a plurality of light emitting diode structures, each structure comprising a substrate coated with a first reflective material; an electrode coated with a second reflective material, one or more layers of light emitting material, the layers disposed between the substrate and electrode; wherein in use, the first reflective material and second reflective material reflects light out via at least one light emitting surface of the structure and in a direction away from the electrode.

The plurality of light emitting diode structures may be electrically connected in parallel.

The plurality of light emitting diode structures may be electrically connected in series.

The plurality of light emitting diode structures may be electrically connected using wire bonding.

The lamp device may further comprise a casing for reflecting light from the plurality of light emitting diode structures in a desired direction.

The casing may be in a spherical shape.

In accordance with a third aspect of the present invention, there is provided a method of forming a light emitting diode structure, the method comprising coating a substrate with a first reflective material; coating an electrode with a second reflective material, providing one or more layers of light emitting material, the layers disposed between the substrate and electrode; wherein in use, the first reflective material and second reflective material reflects light out of the structure via at least one light emitting surface and in a direction away from the electrode.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1(a) is a schematic top view diagram of a broad side light emitting diode (BSLED) structure in an example embodiment.

FIG. 1(b) is a schematic side view diagram of the structure.

FIG. 2(a) is a microscope picture of a BSLED structure sample.

FIG. 2(b) is a schematic diagram of the BSLED structure sample.

FIG. 2(c) is a microscope picture of a control LED.

FIG. 2(d) is a schematic diagram of the control LED.

FIG. 3 is a graph of light power (μm) versus injection current (mA) when a power meter is disposed about 1.5 cm away from both the BSLED structure sample and the control LED.

FIG. 4 is a graph of current (mA) versus voltage (V).

FIG. 5(a) is a schematic top view diagram showing a BSLED structure in another example embodiment.

FIG. 5(b) is a schematic side view diagram of the BSLED structure.

FIG. 6(a) is a schematic top view diagram showing a BSLED structure in another example embodiment.

FIG. 6(b) is a schematic side view diagram of the BSLED structure.

FIG. 7 is a schematic side view diagram illustrating two BSLED structures connected in parallel in an example embodiment.

FIG. 8 is a schematic side view diagram illustrating two BSLED structures connected in series in another example embodiment.

FIG. 9 is a schematic side view diagram showing two BSLED structures connected in parallel using wire bonding in another example embodiment.

FIG. 10(a) is a schematic front view diagram of a lamp device in another example embodiment.

FIG. 10(b) is a schematic side view diagram of the lamp device.

FIG. 11(a) is a schematic diagram illustrating a control top emitting LED fitted to a light spreading film in yet another example embodiment.

FIG. 11(b) is a schematic diagram illustrating a BSLED structure fitted to a light spreading film in the example embodiment.

FIG. 12 is a schematic diagram illustrating a BSLED structure fitted to two light spreading films in yet another example embodiment.

FIG. 13 is a schematic flowchart for illustrating a method of forming a light emitting diode structure in an example embodiment.

### DETAILED DESCRIPTION

The example embodiments described herein can provide broad area side-emitting semiconductor light emitting diodes, e.g. Ga(In)N/Sapphire based LEDs, so that it is possible to enhance light extraction efficiency, increase thermal conductivity and provide more lamp design freedom for e.g. high power and backlighting applications. In the example embodiments, a side-emitting LED can have light output from one or more sides instead of from the top surface or substrate end, as exhibited by e.g. typical Ga(In)N LEDs. Preferably, light is emitted from the broad areas of a side-emitting LED (BSLED).

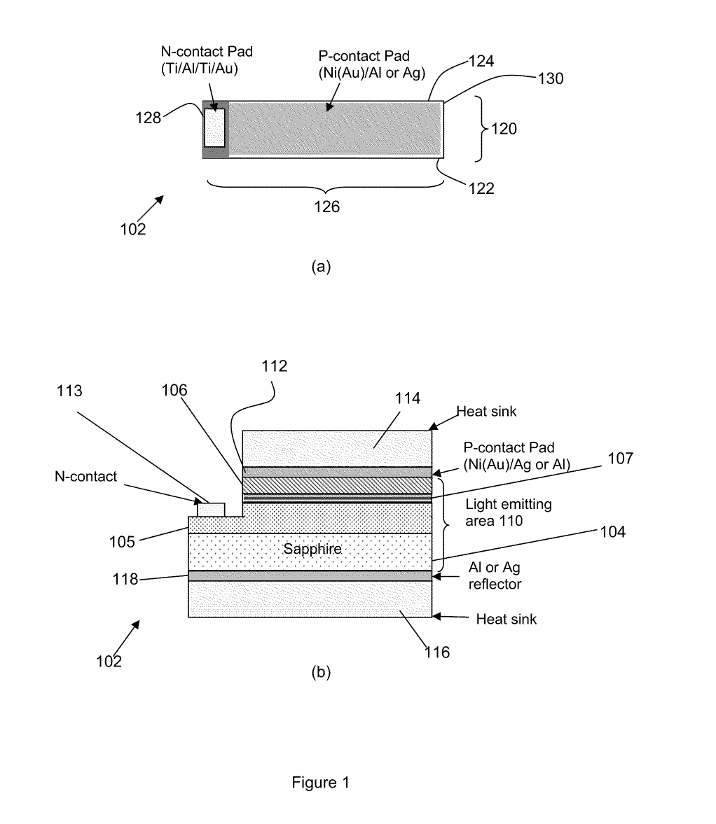

FIG. 1(a) is a schematic top view diagram of a BSLED structure 102 in an example embodiment. FIG. 1(b) is a schematic side view diagram of the structure 102. The structure 102 comprises a sapphire substrate 104, a n-GaN layer 105 formed on the substrate 104, an active region having an InGaN quantum well structure 107 formed on the n-GaN layer 105, a p-GaN layer 106 formed on the InGaN quantum well structure 107, a p-contact 112 formed on the p-GaN layer 106 and a n-contact 113. The sapphire substrate 104, the n-GaN layer 105, the InGaN quantum well structure 107 and the p-GaN layer 106 form a light emitting area 110. It will be appreciated that undoped GaN may be provided between the substrate 104 and the n-GaN layer 105.

The structure 102 can be a GaN based LED structure and grown by metal organic chemical vapour deposition (MOCVD) using typical growth conditions. One example of the LED structure growth can be like follows: firstly, a low temperature GaN buffer is grown in the range of about 520° C. to 550° C. for a thickness of about 25 nm to facilitate the nucleation of GaN on the sapphire substrate 104. A high temperature undoped GaN layer is grown to a thickness of about 2 μm at around 1020° C., followed by a highly silicon-doped layer of GaN with thickness of about 2-2.5 μm to function as the n-GaN layer 105. N-type doping is achieved using SiH4. The InₓGa₁₋ₓN multi-quantum well structure (MQW) structure 107 is then grown. In the example embodiment, the well thickness can vary between about 2 nm and 5 nm, the In composition x can vary between 0 and 0.4 and the number of quantum wells can vary between 1 and 5. The MQW structure 107 has 7-30 nm undoped GaN confinement layers. The Mg doped p-GaN layer 106 is finally grown to a thickness of about 50 nm to 800 nm. The p-contact 112 and n-contact 113 are evaporated using an electron beam evaporation or sputtering system and alloyed using thermal annealing at different temperature and gas ambient, e.g. N2 gas ambient for n-contact and air ambient for p-contact.

In the example embodiment, the top p-GaN layer 106 and the bottom sapphire substrate 104 are provided with metal mirrors respectively (see 112 and 118) using e-beam evaporation or sputtering to reflect the light from the light emitting area 110. In the example embodiment, the mirror 118 is coated on the backside of the substrate 104. In the example embodiment, the metal coating on the sapphire substrate can be Ag or AI. Alternatively, a double side polished Sapphire substrate may be used for this purpose. The top metal mirror also functions as the p-metal contact 112 in the example embodiment. The mirror or p-metal contact 112 can comprise Ni/Au/AI or Ni/AI or Ni/Ag or Ni/Au/Ag or other combinations including Ag or Al. The Ni and Au thickness is less than about 10 nm, e.g. about 5 nm and the Ag or Al thickness is more than about 10 nm, e.g. between about 10 nm to 5 μm, i.e. thick enough to be a reflector.

In the example embodiment, for the n-contact 113, the n metal is deposited after exposing a n-GaN layer (not shown) using plasma etching. The n-contact 113 can comprise Ti/AI or Ti/Al/Ti/Au. The n-contact 113 is either connected to the bottom sapphire substrate 104 metal mirror layer 118 or directly connected to an external bonding pad (not shown). The BSLED structure 102 on a chip can be packaged in between two metal heat sinks 114, 116 to enhance heat dissipation during high power operation.

In the example embodiment, the structure 102 is in a form such that the structure 102 gives a large length to breath ratio (see numerals 126 and 120 respectively) to increase the effective light emission area. For example, given a GaN wafer area of 1000 um×1000 um, the BSLED structure 102 can be made in the form of a 5000 um×200 um bar. The total light emission area for such a BSLED structure from the two long side cross sections (compare 122, 124) is about 5000 um×350 um (assuming that sapphire thickness is about 350 um).

It will be appreciated by a person skilled in the art that the light emission area of the BSLED structure 102 is larger than that of a typical LED. The ratio of light emitted from the two short side cross sections (compare 128, 130) to the effective long sides (compare 122, 124) is also more than 15 times smaller than the ratio of light escaping from the side walls to the top surface emission in a typical LED structure.

In another example embodiment, a BSLED structure sample is fabricated for comparison with a same sized typical top emitting LED acting as a control LED. Both the BSLED structure and the control LED are fabricated from a same piece of LED wafer with an emission wavelength around 530 nm (e.g. green color) grown on a double side polished Sapphire substrate.

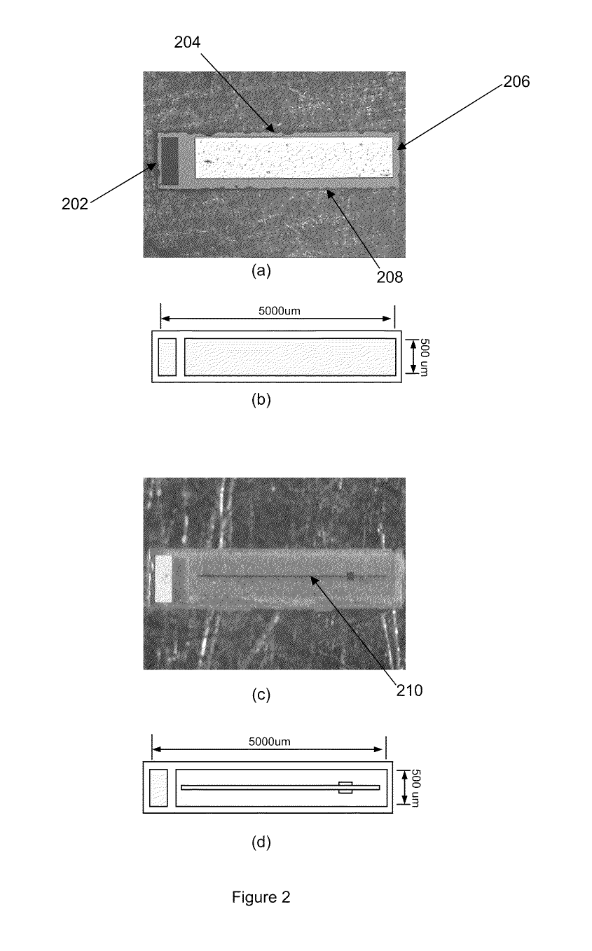

FIG. 2(a) is a microscope picture of the BSLED structure sample. FIG. 2(b) is a schematic diagram of the BSLED structure sample. FIG. 2(c) is a microscope picture of the control LED. FIG. 2(d) is a schematic diagram of the control LED.

In the example embodiment, the BSLED structure is about 5000 um long and 500 um wide. For both the control LED and BSLED structure, the metal layers for the n-contact comprise 10 nm Ti/300 nm Al/10 nm Ti/100 nm Au. For the control LED, the p-contact metal comprises 5 nm Ni/5 nm Au and for the BSLED structure, the p-contact metal comprises 5 nm Ni/5 nm Au/500 nm Al. The additional Al of about 500 nm on the p-contact area for the BSLED structure acts as a mirror to reflect light and to allow light to emit from four sides (compare 202,204,206,208) of the BSLED structure. In addition, the control LED and the BSLED structure each has about 400 nm of Al deposited on the backside of the respective sapphire substrates using e-beam evaporation or sputtering to prevent light from emitting from the substrate side. A line 210 observed in FIG. 2(b) is the metal contact pad on top of the semitransparent Ni/Au current spreading layer.

In the example embodiment, the BSLED structure and the control LED are tested by probing on the respective p-contact pads and n-contact pads. A probe station is used for testing the BSLED structure and the control LED. The diced chips containing the BSLED structure and the control LED are put directly on a copper base of the probe station with the respective p-contact sides facing upwards (compare orientation of structure 102 of FIG. 1). The copper base can act as a bottom heat sink (compare 116 of FIG. 1). In other words, the sapphire substrate of the BSLED structure and the control LED is in contact with the copper base of the probe station.

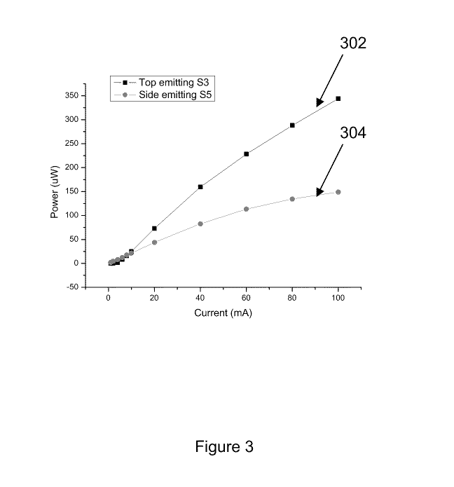

FIG. 3 is a graph of light power (μm) versus injection current (mA) when a power meter of the probe station is disposed about 1.5 cm away from both the BSLED structure and the control LED. The distance can not be smaller for the control LED due to restrictions of using probes on the top emitting structure of the control LED. The power meter comprises a detector chip that is an active part that reacts with light and converts light to electrical signals for display in the power meter. Plot 302 shows the results for the control LED and plot 304 shows the results for the BSLED structure. Since the BSLED structure has a larger light divergence angle in the p-n junction direction than the control LED and since the detector chip has a limited size, the absolute power read from the power meter for the BSLED structure at the same distance is smaller (compare 302 and 304). If considering light emission from two long edge facets (compare 204, 208 of FIG. 2) or all four facets (compare 202, 204, 206, 208 of FIG. 2) from the BSLED structure, the total power is higher at low currents than the top emitting control LED and comparable with the control LED at high injection currents.

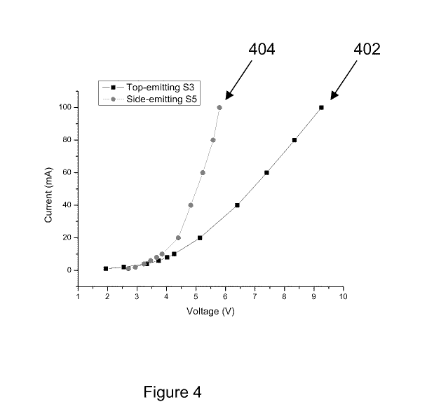

FIG. 4 is a graph of current (mA) versus voltage (V). Plot 402 shows the result for the control LED and plot 404 shows the results for the BSLED structure, It can be observed that the BSLED structure has better I-V characteristics at high currents than the control LED. It can also be observed that the BSLED structure uses a smaller voltage at high currents as compared to the control LED.

Further, a chromaticity meter is used to measure the luminance of LED chips. The results are shown in Table 1 below.

TABLE 1

| | I (mA) | V (V) | Cd/m2 | x | Y |
|---|---|---|---|---|---|
| BSLED (S2) | 20 | 4.15 | 34300 | 0.271 | 0.688 |
| | 40 | 4.89 | 111000 | 0.255 | 0.691 |
| Top emitting (S4) | 20 | 4.68 | 73400 | 0.228 | 0.731 |
| | 40 | 6.00 | 114000 | 0.224 | 0.742 |

It can be observed that the BSLED structure has better electrical and optical properties than the top emitting control LED at large sizes. The BSLED structure and the top emitting LED shows similar luminance. The (x, y) chromaticity data also indicates an absorbing effect by the thin Au metal contact layer of the control LED. The difference in the x, y value between the BSLED structure and the control LED is significant and can be seen clearly as two different points in the International Commission on Illumination (CIE) chromaticity diagram (not shown). The top emitting control LED has colour shifted towards a shorter wavelength side as compared to the BSLED structure. This could be due to the non-flat transmitivity of the Ni/Au versus wavelength when light passes through the top p metal contact of the control LED. This absorbing effect appears to be eliminated in the BSLED structure.

In the example embodiment, the BSLED structure can advantageously dissipate heat through the top and substrate surfaces (ie. via two heat sinks), in stark contrast to only through a bottom contact for a typical top emitting LED or only through a top contact for a typical bottom emission LED (ie. only via one heat sink). This advantage can be important for high brightness, high power applications when the chip size is big, e.g. larger than about 1 mm², and the injection current is high, e.g. larger than about 700 mA. Another advantage of the BSLED structure is that the current spreading at high injection currents is better than typical top emitting LEDs that typically use a thin Ni/Au layer with a thickness about of 5 nm/5 nm (compare FIG. 4) ie. the p-contact of the BSLED structure of the example embodiment can be made more than 500 nm thick. Further, since there is no semi-transparent metal layer in the emission path to damp the light emission, the BSLED structure has a higher transmittivity than a typical LED. In addition, the observable light emission area of the BSLED structure is larger than a typical LED.

Following the comparison of a control LED with the BSLED structure, another example embodiment is described below for improving light extraction from the BSLED structure using facet coating.

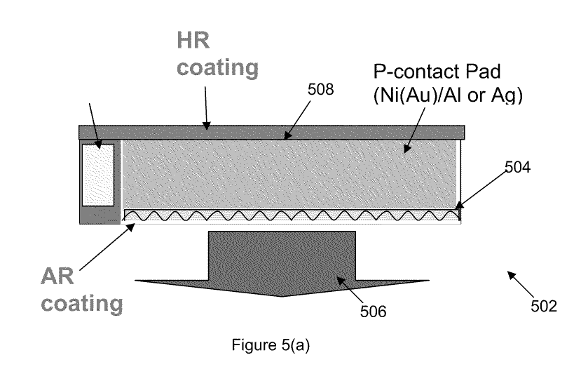

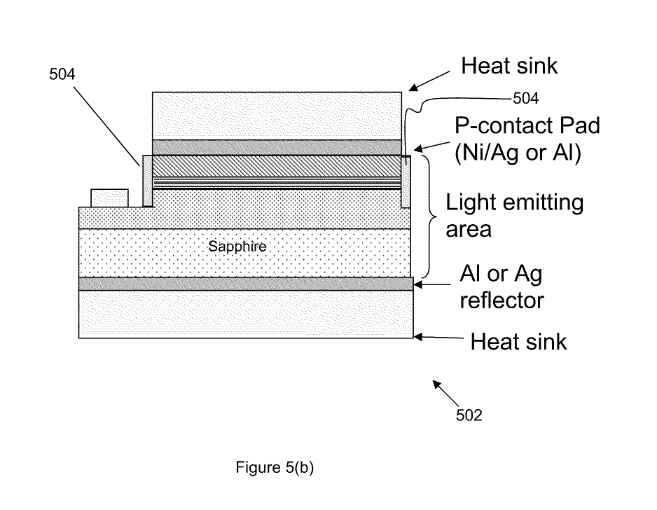

FIG. 5(a) is a schematic top view diagram showing a BSLED structure 502 in another example embodiment. FIG. 5(b) is a schematic side view diagram of the BSLED structure 502.

In this example embodiment, the BSLED structure 502 comprises side wall passivation (see 504) formed using dielectric materials such as SiO2 or SiON with a refractive index n value of about 1.6. The dielectric material can be deposited by chemical vapour deposition (CVD), e.g. including plasma enhanced CVD, or sputtering. It will be appreciated that an additional process step, such as for re-positioning the structure, is taken to deposit the dielectric material on one side of the BSLED structure 502. The dielectric material with a smaller refractive index can work like an anti-reflection coating to e.g. GaN based semiconductor layers and can easily reduce the Snell reflection from about 20% to below about 4%. The thickness of the dielectric material can be chosen to be about ¼n λ, where n is the refractive index and λ is wavelength, to further enhance the anti-reflection effect. This is one advantage over a typical top emitting LED given that a dielectric passivation layer cannot be used in a top emitting LED since there is a metal contact layer on top of the p-GaN surface of the typical top emitting LED.

If it is preferred to have light emission from only one light emitting long edge in the example embodiment (see 506), the other long edge 508 is coated with high reflective dielectric coatings, e.g. using pairs of SiO₂/TiO₂ or SiO₂/Si₃N₄ with each having a thickness of a quarter wavelength ¼n λ. It will be appreciated by a person skilled in the art that this can be carried out either on an etched side wall using a side deposition technique or on both the etched side wall and a side of the sapphire substrate after chip bar dicing using a facet coating technique e.g. e-beam evaporation or ion-beam assisted sputtering. It will be appreciated that one more process step is taken to have a high reflective dielectric coating on only one side. It will also be appreciated that the short-side edges can also be coated high reflective dielectric coatings to enhance light emission from only one light emitting long edge, if desired.

Following the description of the example embodiment of improving light extraction from the BSLED structure using facet coating, another example embodiment is described below for improving light extraction from the BSLED structure using surface roughening.

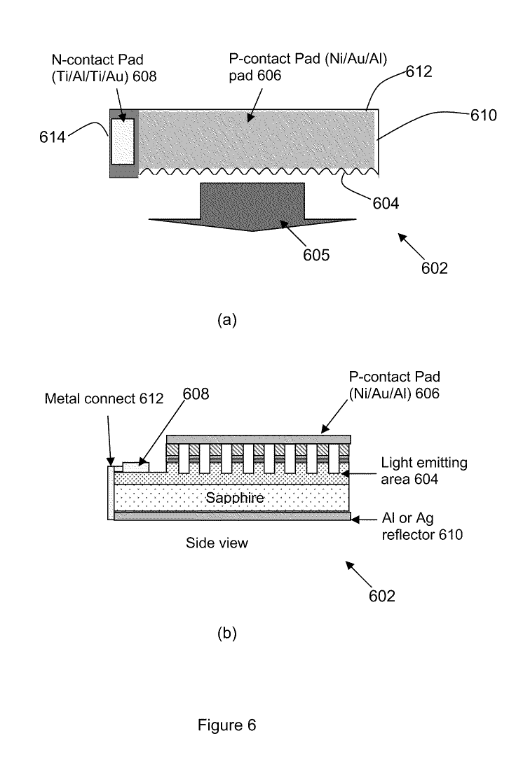

FIG. 6(a) is a schematic top view diagram showing a BSLED structure 602 in another example embodiment. FIG. 6(b) is a schematic side view diagram of the BSLED structure 602.

In the example embodiment, the BSLED structure 602 comprises a zigzag or saw teeth type edge 604. The edge 604 can be formed using standard photolithography and etching techniques. The zigzag or saw teeth edge 604 can eliminate total internal reflection (TIR) and enhance side emission (see 605). The angle and shape of the teeth of the edge 604 can be designed for maximum effect. For example, “sharp” triangular type teeth can be more efficient in breaking the total internal reflection than rectangular shape teeth on the edge 604. The edge 604 can be formed at the same time during the patterning and etching of e.g. a p-mesa structure. The edge 604 can alternatively be formed directly via die cutting. Thus, no additional processing steps are required. This is in contrast to fabricating a typical top emitting LED where another step of patterning and etching is typically required for creating structures on the top surface. In addition, it will be appreciated that the cross-sectional shape of an etched surface structure in a typical top emitting LED cannot be varied arbitrarily due to the nature of the plasma etching while the side wall in the BSLED structure 602 can advantageously be patterned and etched to any desired shape through a lithography process. Further, a roughened surface typically affects the conductivity of the top emitting LED while for the BSLED structure 602, advantageously, the irregular side wall (see edge 604) does not affect the metal contacts (e.g. 606, 608) of the BSLED structure 602.

In the example embodiment, the zigzag pattern is formed on one edge 604. The other edges (ie. 610, 612, 614) are not processed so as to have more light emission from that edge 604. It will be appreciated that all the edges (i.e. 604, 610, 612, 614) can be processed to each have a zig zag pattern or saw teeth type edge, if desired.

In the example embodiment, the n-contact 608 is connected to the reflector surface 610 of the sapphire substrate via a metal connect 612 as an electrical connection.

Following the description of the example embodiment of improving light extraction from the BSLED structure using surface roughening, other example embodiments are described below for high power, high brightness applications e.g. for lamp devices.

In other example embodiments, a plurality of BSLED structures can be stacked or connected for high power, high brightness applications.

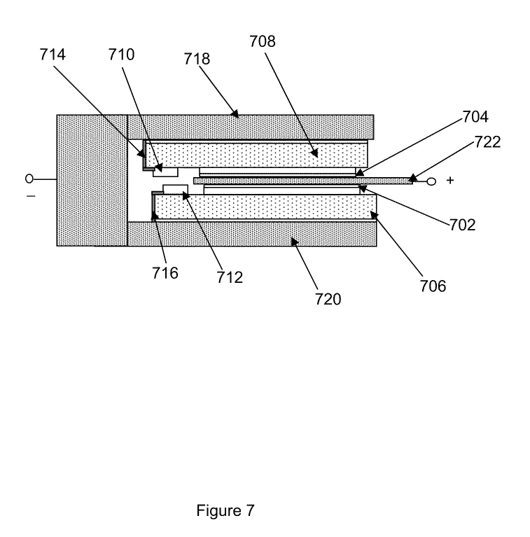

FIG. 7 is a schematic side view diagram illustrating two BSLED structures connected in parallel in an example embodiment. In this example embodiment, respective p-contacts 702, 704 of the BSLED structures 706, 708 are connected to a “+” pole of a power supply (not shown). Respective n-contacts 710, 712 are connected to a “−” pole of the power supply using metal contacts 714, 716. Thus, the p-contacts 702, 704 are facing each other. The metal contacts 714, 716 are connected to the “−” pole using thin metal blocks 718, 720. The p-contacts 702, 704 are connected to the “+” pole using a thin metal block 722. The metal blocks 718, 720, 722 can function as heat sinks and electrodes. Thus, wire bonding is not used in this example embodiment.

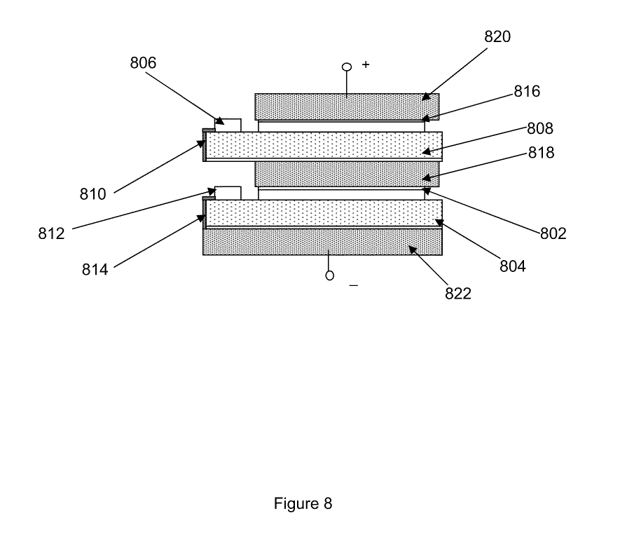

FIG. 8 is a schematic side view diagram illustrating two BSLED structures connected in series in another example embodiment. In this example embodiment, a p-contact 802 of a BSLED structure 804 is in contact with an n-contact 806 of another BSLED structure 808 via a metal contact 810. An n-contact 812 of the BSLED structure 804 is connected to a “−” pole of a power supply (not shown) via a metal contact 814. A p-contact 816 of the BSLED structure 808 is connected to a “+” pole of the power supply. Thus, the p-contacts 802, 816 are facing in the same direction. The p-contacts 802, 816, and the metal contact 814 are in electrical connection with thin metal blocks 818, 820, 822 respectively. The metal blocks 818, 820, 822 can function as heat sinks and electrodes. Thus, wire bonding is not used in this example embodiment.

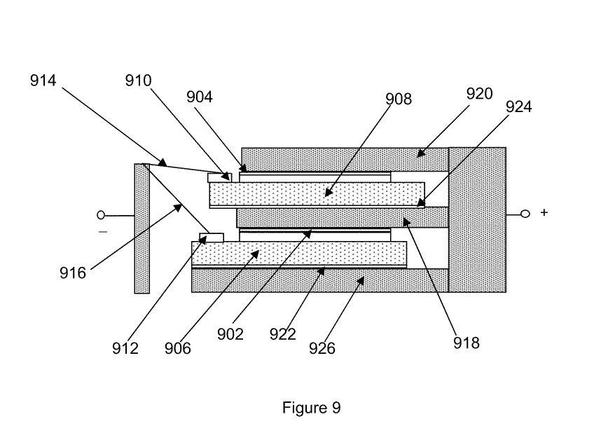

FIG. 9 is a schematic side view diagram showing two BSLED structures connected in parallel using wire bonding in another example embodiment. In this example embodiment, respective p-contacts 902, 904 of the BSLED structures 906, 908 are connected to a “+” pole of a power supply (not shown). Respective n-contacts 910, 912 of the BSLED structures 908, 906 are connected to a separate “−” (cathode) pole of the power supply using wire bonding (see e.g. 914, 916). The p-contacts 902, 904 are in electrical connection with thin metal blocks 918, 920 respectively. Thus, the metal blocks 918, 920 can function as heat sinks and anodes. Respective sapphire substrates 922, 924 of the BSLED structures 906, 908 are connected to metal blocks 926, 918 respectively. The metal blocks 926, 918 function as heat sinks for the sapphire substrates 922, 924.

In the above example embodiments, stacking up LEDs can reduce floor area and can allow more LEDs to be arranged in a 3D space. Thus, the plurality of BSLED structures can lead to more luminance. Further, fin like heat sinks can be attached to sides of LED chips for enhancing heat dissipation. A plurality of BSLED structures can be used to form multi-chips.

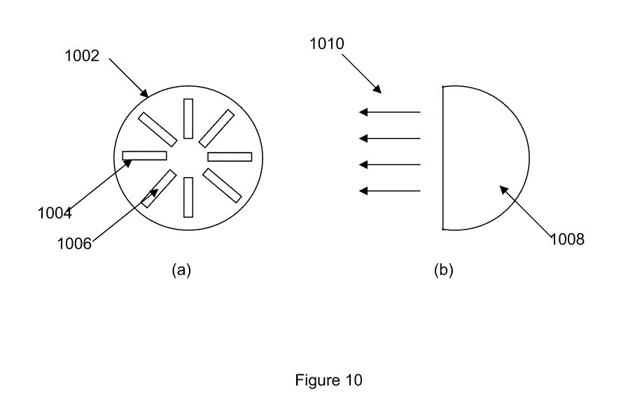

FIG. 10(a) is a schematic front view diagram of a lamp device 1002 in another example embodiment. In the example embodiment, the lamp device 1002 comprises a plurality of BSLED structures e.g. 1004, 1006 arranged in a 3D space. FIG. 10(b) is a schematic side view diagram of the lamp device 1002. Light emission from the sides of the BSLED structures e.g. 1004, 1006 can be more fully utilized by using a spherical or bowel like casing 1008 to channel the light to one direction e.g. see 1010. The casing can be made of high reflection metal.

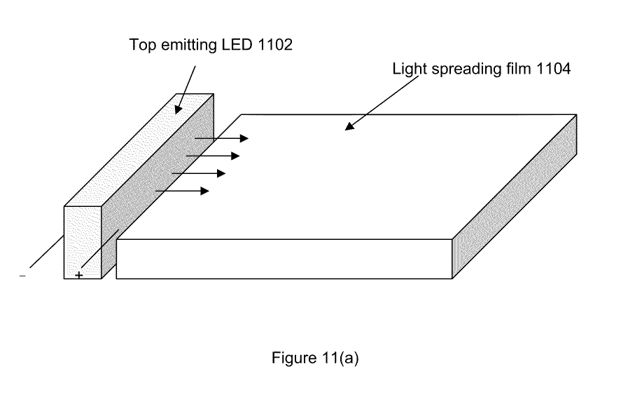

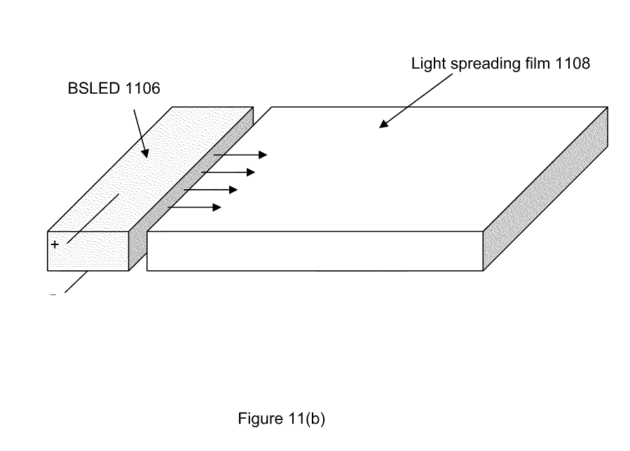

In yet another example embodiment, a BSLED structure is used in LCD backlighting by directly burying the BSLED structure or mounting the BSLED structure into a light spreading thin film. FIG. 11(a) is a schematic diagram illustrating a control top emitting LED 1102 fitted to a light spreading film 1104. FIG. 11(b) is a schematic diagram illustrating a BSLED structure 1106 fitted to a light spreading film 1108. As can be observed, the thin side emitting LED or the BSLED structure 1106 with top and bottom electric contacts is easier to fit into the thin light spreading film 1108 as compared to the wide control top emitting LED 1102 with two electrical contacts parallel to the thin film 1104.

It will be appreciated that both the two long edges or all four edges of the BSLED structure can have light emission in back lighting architect designs.

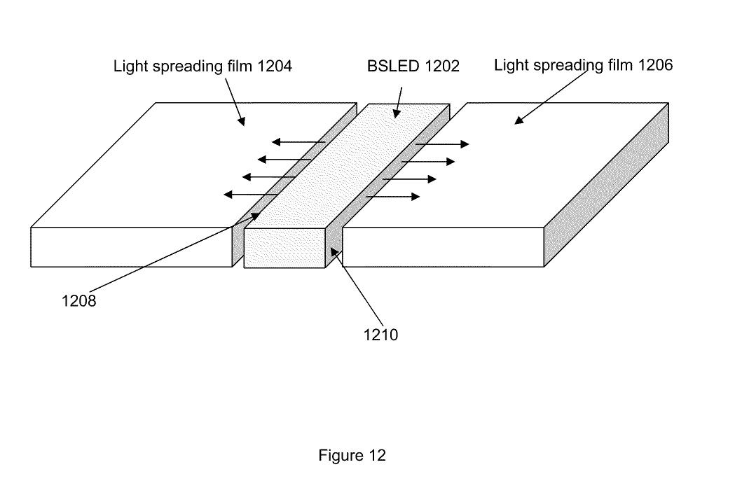

FIG. 12 is a schematic diagram illustrating a BSLED structure 1202 fitted to two light spreading films 1204 and 1206 in yet another example embodiment. In the example embodiment, the BSLED structure 1202 comprises two long edges 1208, 1210 fitted to the light spreading films 1204 and 1206 respectively.

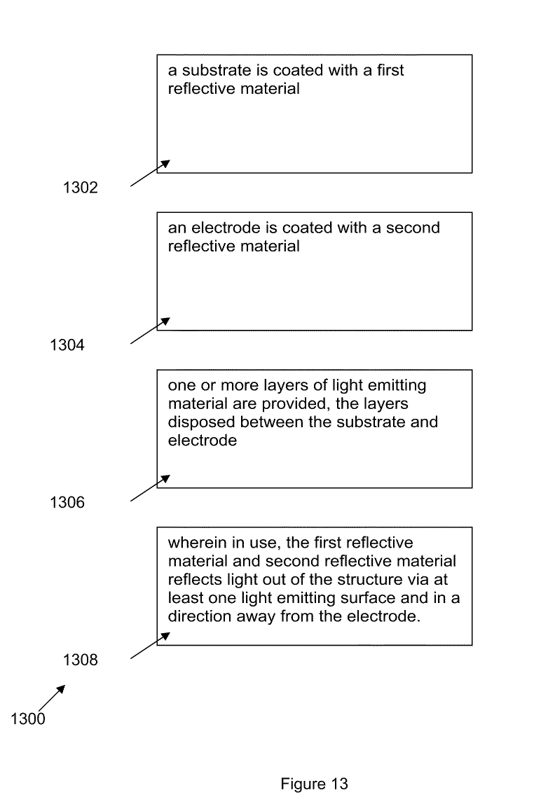

FIG. 13 is a schematic flowchart 1300 for illustrating a method of forming a light emitting diode structure in an example embodiment. At step 1302, a substrate is coated with a first reflective material. At step 1304, an electrode is coated with a second reflective material. At step 1306, one or more layers of light emitting material are provided, the layers disposed between the substrate and electrode. At step 1308, wherein in use, the first reflective material and second reflective material reflects light out of the structure via at least one light emitting surface and in a direction away from the electrode.

The above described example embodiments can provide light emission from the side facets of a LED structure. The top and substrate end surfaces of the LED structure are coated with metal layers in the example embodiments. The metal layers can function as electrical contacts, current spreading, reflection mirror and heat dissipation layers. Current spreading in high injection states can be handled in the example embodiments. Heat generated in the example embodiments can be dissipated through both the top and substrate end metal layers that can be in turn connected to heat sinks. In one described example embodiment with zigzag patterning, the TIR and Snell reflection can be solved in the BSLED structure. The zigzag patterning of a long edge can enhance the light extraction. The zigzag patterning can be done in the same step of the mesa etching. The problem can also be solved directly by dicing from the top p-GaN surface. In one described example embodiment with a dielectric passivation layer, the Snell reflection can be reduced by the dielectric passivation layer itself and can be minimized to the least through preferred dielectric layer thickness deposition thickness, such as ˜¼n λ. The thickness controlled dielectric passivation layer deposition can reduce interface reflection and further enhance light extraction from a LED chip. In the example embodiments, the side emission BSLED structure can also provide flexibility in lamp or other light apparatus designs. As for LCD backlighting, the BSLED structure of the described example embodiments can have the light spread into a light spreading film by mounting and burying the BSLED structure inside the film. Using the BSLED structure for LCD backlighting can lead to cost savings since fewer LEDs are required. There is also improved uniformity over the LED lifetimes. Also, there is likely to be fewer LED drive problems. For high power applications using multi-chips, the BSLED structure of the described example embodiments can be mounted in 3D either by vertically or laterally stacking chips to make a lamp or other light apparatus design more compact. This is advantageous over typical LEDs since typical LEDs are usually mounted side by side in a 2D surface.

The above described example embodiments can be suitable for high power high brightness applications where a large chip size and high current injections are used. The relatively larger length to breath ratio in the BSLED structure of the described example embodiments can get at least similar, if not more light, out from the same amount of GaN material as compared to a typical LED. The top and substrate side surface coating with e.g. Ag or Al layers can act as mirrors to have light emit only from side facets. The surface coatings can make current spreading across a whole surface in a LED uniform and can provide heat dissipation. Both current spreading and heat dissipation are considerable at high current injections. The above described example embodiments can also provide a side emitting LED structure with a 360 degree light emission as compared to a 180 degree light emission from a typical top emitting LED.

The BSLED structure of the described example embodiments can be used for LED fabrication and applicable to LED applications. The BSLED structure of the described example embodiments can be especially useful for high power and high brightness applications, such as solid state light, LED backlighting. The BSLED structure of the described example embodiments can also be applied to organic or polymer based light emitting devices and apparati.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A light emitting diode structure, the structure comprising
a substrate coated with a first reflective metal material;
an electrode coated with a second reflective metal material;
one or more layers of light emitting material, the layers disposed between the substrate and electrode; and
wherein the first reflective metal material and the second reflective metal material are each configured for conducting heat from the structure; and further
wherein in use, the first reflective metal material and second reflective metal material reflects light out of the structure via at least one light emitting surface and in a direction substantially parallel to the substrate.

2. The structure as claimed in claim 1, wherein said at least one light emitting surface comprises a zigzag/saw teeth type edge.

3. The structure as claimed in claim 1, wherein said at least one light emitting surface comprises a layer of passivation material for reducing light reflection.

4. The structure as claimed in claim 1, wherein for light emission via one light emitting surface, at least one other light emitting surface comprises a layer of reflective material for enhancing light emission via said one light emitting surface.

5. The structure as claimed in claim 1, wherein for light emission via one light emitting surface, other light emitting surfaces comprise a layer of reflective material for enhancing light emission via said one light emitting surface.

6. The structure as claimed in claim 1, wherein the electrode comprises an electrode material of about 500 nm thick.

7. The structure as claimed in claim 1, wherein the structure is in the form of a rectangular block comprising two long edges, the rectangular block having a length to breadth ratio of about 25:1 or about 10:1.

8. The structure as claimed in claim 7, wherein one or both of the long edges are coupled to respective light spreading films disposed parallel to the structure.

9. The structure as claimed in claim 1, wherein the substrate, the electrode or both are connected to a heat sink.

10. The structure as claimed in claim 1, wherein the first reflective metal material and the second reflective metal material each comprises Ag, Al or both.

11. The structure as claimed in claim 1, wherein the first reflective metal material and the second reflective metal material is each more than about 10 nm thick.

12. A lamp device comprising a plurality of light emitting diode structures, each structure comprising
a substrate coated with a first reflective metal material;
an electrode coated with a second reflective metal material,
one or more layers of light emitting material, the layers disposed between the substrate and electrode; and
wherein the first reflective metal material and the second reflective metal material are each configured for conducting heat from the structure; and further
wherein in use, the first reflective metal material and second reflective metal material reflects light out via at least one light emitting surface of the structure and in a direction substantially parallel to the substrate.

13. The lamp device as claimed in claim 12, wherein each structure is in the form of a rectangular block comprising two long edges, the rectangular block having a length to breadth ratio of about 25:1 or about 10:1.

14. The lamp device as claimed in claim 12, wherein the plurality of light emitting diode structures are electrically connected in parallel.

15. The lamp device as claimed in claim 12, wherein the plurality of light emitting diode structures are electrically connected in series.

16. The lamp device as claimed in claim 12, wherein the plurality of light emitting diode structures are electrically connected using wire bonding.

17. The lamp device as claimed in claim 12, the lamp device further comprising a casing for reflecting light from the plurality of light emitting diode structures in a desired direction.

18. The lamp device as claimed in claim 17, wherein the casing is in a spherical shape.

19. A method of forming a light emitting diode structure, the method comprising
coating a substrate with a first reflective metal material such that the first reflective metal material is configured for conducting heat from the structure;
coating an electrode with a second reflective metal material such that the second reflective metal material is configured for conducting heat from the structure,
providing one or more layers of light emitting material, the layers disposed between the substrate and electrode;
wherein in use, the first reflective metal material and second reflective metal material reflects light out of the structure via at least one light emitting surface and in a direction substantially parallel to the substrate.

20. The method as claimed in claim 19, wherein the structure is formed in the form of a rectangular block comprising two long edges, the rectangular block having a length to breadth ratio of about 25:1 or about 10:1.
